(19) United States
(12) Patent Application Publication
(10) Pub. No.: US 2011/0057295 A1
(43) Pub. Date: Mar. 10, 2011

(54) EPITAXIAL SUBSTRATE COMPONENT MADE THEREWITH AND CORRESPONDING PRODUCTION METHOD

(75) Inventor: Andreas Plossl, (US)

(73) Assignee: Osram Opto Semiconductors GmbH

(21) Appl. No.: 12/940,238

(22) Filed: Nov. 5, 2010

Related U.S. Application Data
(63) Continuation of application No. 11/528,722, filed on Sep. 27, 2006.

(30) Foreign Application Priority Data
Sep. 30, 2005 (DE) 10 2005 047 149.8

(51) Int. Cl. H01L 29/20; H01L 33/00

(52) U.S. Cl. 257/615; 438/33; 257/E33.055; 257/E29.089

(57) ABSTRACT

Proposed is a III-V-semiconductor-containing epitaxial substrate comprising at least one layer of porous III-V semiconductor material, together with a corresponding production method. Also specified is a component, particularly an LED, produced on the proposed epitaxial substrate, and a corresponding production method.

### CROSS REFERENCE TO RELATED APPLICATION

This application is a continuation application (and claims the benefit of priority under 35 U.S.C. §120) of U.S. patent application Ser. No. 11/528,722, filed Sep. 27, 2006, which claims the benefit of priority under 35 U.S.C. §119 of German Patent Application No. 10 2005 047 149.8, filed Sep. 30, 2005. The disclosure of each of these prior applications is incorporated herein by reference in its entirety.

### TECHNICAL FIELD

This application relates to an epitaxial substrate, particularly for producing thin-film semiconductor chips based on III-V semiconductors, together with a method of making said substrate. It further relates to a component made with the epitaxial substrate, particularly a radiation emitting component and especially an LED, a laser or an IR diode, and a method of making said component.

### BACKGROUND

The use of thin-film semiconductor chips has been steadily gaining prevalence in recent years, especially in the production of radiation emitting components such as LEDs and lasers.

Such a component based on thin-film technology is described for example in DE 100 59 532. In its production, a light-emitting diode structure is grown on an epitaxial substrate and then bonded to an acceptor substrate, and the light-emitting diode structure is then separated from the epitaxial substrate. Heretofore, the method used to release the film, once it has been bonded to the acceptor substrate, has usually been to first thin the epitaxial substrate by grinding and then to remove the rest of the epitaxial substrate in an etching step. The original epitaxial substrate is completely destroyed in the process. No reuse of the epitaxial substrate is possible.

The reuse of epitaxial substrates is particularly desirable, since these are usually expensive single-crystal substrates.

The article A. Plöβl et al., “Silicon-on-Isolator: Materials Aspects and Applications,” Solid-State Electronics 44 (2000), 775-782, describes another method of fabricating silicon-based thin-film semiconductor chips known as the ELTRAN method. A desired structure is grown on a silicon epitaxial substrate comprising a porous layer. This structure is then bonded to an acceptor substrate, and the epitaxial growth substrate is removed by cleaving the porous layer from the grown structure and the acceptor substrate affixed to it. This method has the advantage that the single-crystal silicon epitaxial substrate can be reused after separation. The method cannot be transferred to III-V semiconductor systems, particularly because of the different types of atoms involved.

### SUMMARY

Certain embodiments disclosed herein specify a way of removing substrates that is applicable to another material system.

Disclosed herein is an epitaxial substrate containing III-V semiconductors comprises at least one layer of porous III-V semiconductor material. Any desired III-V semiconductor structures can be grown above the porous layer. A substrate of this kind provides the advantage that the structures grown on it can be released at a later time by destroying the porous layer or by cleaving the porous layer from the original substrate wafer. As for the epitaxial substrate wafer, the portion of the wafer located under the porous layer can be reused, for example after the application of thin-layer technology.

A particularly preferred embodiment provides that the epitaxial substrate is composed primarily of III-V semiconductor materials. Through the use of a porous layer in connection with epitaxial substrates made of III-V semiconductor materials, particularly gallium arsenide wafers, simple cleavage between the grown structures and the wafer can be achieved by the introduction of a layer of porous III-V semiconductor material.

An advantageous embodiment arises if the pore size of the porous layer is larger in a first subregion than it is in a second subregion. In the production of an epitaxial substrate according to the invention, for example a porous layer can be produced on a gallium arsenide wafer by electrochemical oxidation. The pore size within the porous layer can be varied by controlling the electrochemical oxidation. To simplify the subsequent cleavage of the porous layer, parting layers or parting layer regions with large pores are particularly preferred for use with epitaxial substrates according to the invention.

In order to produce desired structures above the porous layer, the porous layer itself should be uniformly overgrown with semiconductor materials. To this end, it is advantageous if the porous layer has a very small pore size at least in one subregion. This is advantageous particularly if this second subregion is located between the first subregion, comprising the large pores, and the growth surface of the epitaxial substrate.

A further particularly preferred embodiment provides that the long-range crystallographic order is preserved within the porous layer. Due to its preserving the long-range crystallographic order, the porous layer can be overgrown in a simple manner with single-crystal layers that have the same crystallographic order as the wafer underlying the porous layer. This can in particular minimize or even completely eliminate lattice defects in the structures that are to be grown on the epitaxial substrate.

Another preferred embodiment provides that the porous layer is overgrown by a III-V semiconductor crystal. The surface of this III-V semiconductor crystal is particularly suitable for growing desired semiconductor structures, for example LED structures.

A particularly advantageous embodiment arises if the epitaxial substrate additionally comprises at least one etch-stop layer. The at least one etch-stop layer is located particularly in the vicinity of the porous layer. If the porous layer is to be destroyed by the use of wet chemical etching to release the structures grown on the epitaxial substrate, then one or more etch-stop layers can be employed to protect the layers surrounding the porous layer from the etching solution.

Certain embodiments advantageously additionally provide that the pore size within the porous layer exhibits at least one gradient. For example, the pore size within the porous layer can be varied such that it decreases from a center or middle of the layer to both surfaces of the layer. This creates a region in the middle of the porous layer that is particularly easy to cleave or destroy. Furthermore, one or more transition zones to the surfaces of the porous layer, in which zones the pore size progressively decreases, permit or facilitate uniform overgrowth of the layer with a semiconductor crystal, particularly a monocrystalline semiconductor crystal.

A further preferred embodiment arises if at least one light-emitting diode structure is disposed on the surface of the epitaxial substrate. The use of epitaxial substrates according to the invention in fabricating light-emitting diode chips is particularly preferred. The use of thin-layer technology in connection with light-emitting diodes offers in particular the advantage of a higher radiation output, since generated light can be extracted more easily from a thin film.

A further preferred embodiment comprises, on the at least one light-emitting diode structure, at least one bonding layer intended and suitable for subsequent bonding to an acceptor substrate. Such a prepared epitaxial substrate can be immediately bonded to an acceptor substrate, for example by techniques such as wafer bonding, gluing, soldering or tempering. After the epitaxial substrate has been firmly bonded to the acceptor substrate, the porous layer can be cleaved or destroyed. The wafer underlying the original epitaxial substrate can be removed and reused.

One advantageous embodiment relates to thin-film LED chips that have been grown on an epitaxial substrate according to the invention. Such thin-film LED chips can be fabricated at low cost, since after the porous layer has been cleaved or destroyed, the monocrystalline wafer can be reused for additional epitaxy steps.

Also disclosed is a method of making epitaxial substrates. The method preferably includes the following steps: preparing a III-V semiconductor wafer, particularly a gallium arsenide wafer, producing a porous layer on one surface of the semiconductor wafer by electrochemical oxidation, and overgrowing the pores of the porous layer with a semiconductor material, particularly a III-V semiconductor material and especially a gallium arsenide semiconductor. An epitaxial substrate produced in this manner forms the base layer for additional epitaxial steps by means of which any desired semiconductor structures, and particularly III-V semiconductor structures, can be disposed or produced on the epitaxial substrate above the porous layer.

Another preferred embodiment of the method provides that due to control of the electrochemical oxidation, the pore structure of the porous layer has a different average pore size in a first subregion than it has in a second subregion. Through systematic control of the electrochemical reaction, for example the first subregion of the porous layer, which is located farther from the overgrown semiconductor layer, has a larger pore size than a second subregion located closer to that layer. Configuring different subregions with different pore sizes achieves the result that a uniform monocrystalline semiconductor crystal with only a few lattice distortions forms on the side of the epitaxial substrate that is to be overgrown.

An advantageous embodiment of the method arises if after the overgrowth of the porous layer, at least one LED structure is grown on the surface of the overgrown semiconductor crystal.

A further preferred embodiment provides that a bonding layer is applied to the epitaxial substrate above the additional layers. This bonding layer is particularly advantageous if it is used to bond the epitaxial substrate to an acceptor substrate.

A further preferred embodiment of the method provides for bonding the epitaxial substrate to an acceptor substrate by means of a bonding step. The thin-film structures produced can be transferred from the growth substrate to the carrier or acceptor substrate in this way.

A particularly preferred embodiment of a method of making at least one thin-film semiconductor chip provides for applying LED structures to an epitaxial substrate containing a porous layer overgrown by a semiconductor crystal. This epitaxial substrate comprising the applied LED structures is then bonded to an acceptor substrate, and the LED structures above the porous layer are separated from the semiconductor crystal underlying the porous layer by cleaving the porous layer.

The method of making one or more thin-film semiconductor chips advantageously provides for singulating the light-emitting diode structures after detaching the semiconductor material under the porous layer. This singulation can be effected by grinding, sawing, grinding [sic], breaking or other separation techniques.

### DESCRIPTION OF DRAWINGS

Exemplary embodiments illustrated in the figures of the drawing follow. Elements of the same kind are provided with the same reference numerals. Therein:

FIG. 1 is a schematic cross-sectional diagram of an epitaxial substrate,

FIG. 2 is a further schematic cross-sectional diagram of an epitaxial substrate,

FIG. 3 is a third schematic cross-sectional diagram of an epitaxial substrate,

FIG. 4 is a fourth schematic cross-sectional diagram of an epitaxial substrate and

FIG. 5 is a schematic diagram of several method steps of a method illustrated by means of cross sections.

### DETAILED DESCRIPTION

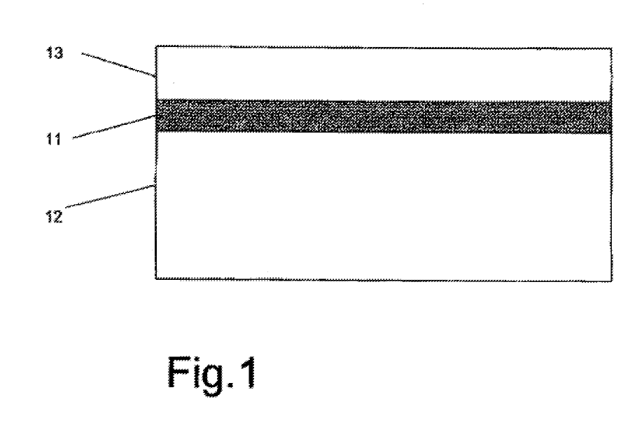

FIG. 1 shows a first exemplary embodiment in a schematic cross section through an epitaxial substrate according to the invention. Disposed on a wafer 12 is a porous layer 11, which is overgrown by a semiconductor crystal 13. Said wafer 12 contains a III-V semiconductor material. The wafer 12 is in particular a gallium arsenide wafer.

The porous layer 11 on the gallium arsenide wafer 12 is produced by electrochemical oxidation. This porous layer 11 can be overgrown by a semiconductor crystal 13. Said semiconductor crystal 13 also comprises a III-V semiconductor material, or a semiconductor material whose lattice constant is matched to the lattice of the wafer 12. The semiconductor crystal comprises for example gallium arsenide (GaAs), indium gallium arsenide (InGaAs), gallium aluminum arsenide (GaAlAs), indium gallium aluminum arsenide (InGaAlAs) or any other desired III-V semiconductor materials. In particular, the long-range crystallographic order of the wafer 12 is preserved in semiconductor crystal 13 via porous layer 11.

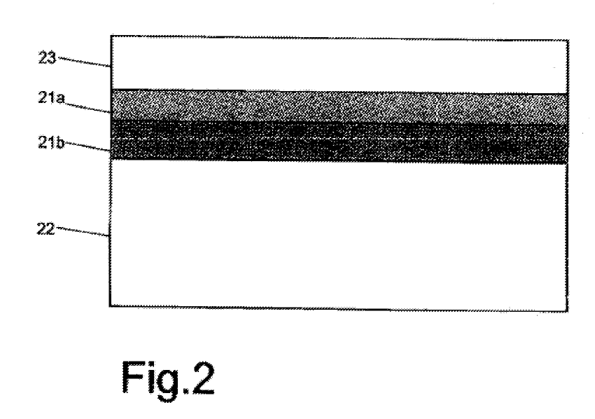

FIG. 2 shows another embodiment of an epitaxial substrate according to the invention. A III-V semiconductor material containing wafer 22, particularly a gallium arsenide wafer, is topped by a porous layer composed of two subsidiary layers 21a, 21b. A semiconductor crystal 23 is disposed on said porous subsidiary layers 21a, 21b. The porous layer has a larger average pore size in a first subregion 21b than in a second subregion 21a. The porous layer 21a, 21b is produced for example by electrochemical oxidation of the wafer 22.

The presence of subregion 21a of the porous layer, having a smaller average pore size, enables the semiconductor crystal 23 grown on its top side to have less tendency to form lattice defects during growth. Different pore sizes in subregions of the porous layer are typically produced by controlling the electrochemical oxidation. However, an additional porous structure, having for example a smaller average pore size, can also be created in a transitional region 21a by adjusting the growth conditions during the production of the semiconductor crystal 23. Almost any desired semiconductor structures can be created by epitaxial growth on the top side of the semiconductor crystal 23 of the epitaxial substrate.

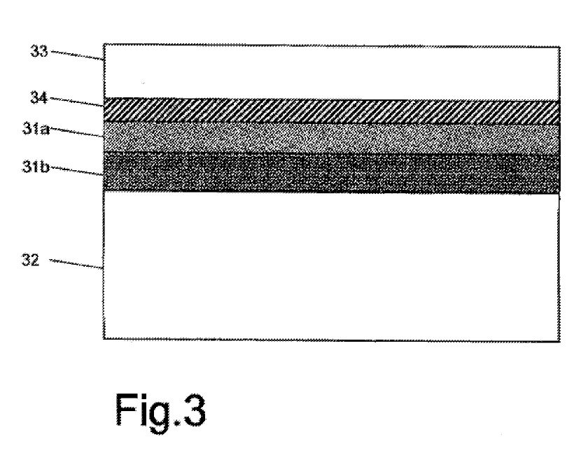

FIG. 3 shows a further exemplary embodiment of an epitaxial substrate. Disposed on a wafer 32 is a porous layer 31a, 31b containing two subregions and having a larger average pore size in one subregion 31b than in a second subregion 31a. Further embodiments provide that the porous layer comprises more than two subregions having different pore sizes. In particular, three or more subregions are possible, a middle subregion having a large average pore size being flanked at its boundary surfaces by porous subregions exhibiting smaller average pore sizes.

In the exemplary embodiment according to FIG. 3, an etch-stop layer 34 is interpolated above the porous layer 31a, 31b. This etch-stop layer 34 is suitable for protecting the semiconductor crystal 33 located above the etch-stop layer 34 against the etching solution if the porous layer 31a, 31b is to be removed via an etching process, particularly a wet chemical etching process.

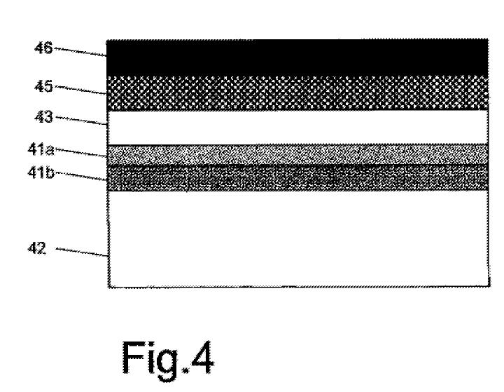

FIG. 4 shows a further embodiment of an epitaxial substrate. Disposed on a wafer 42 is a porous layer 41a, 41b, which has a larger average pore size in a first subregion 41b than in a second subregion 41a. The porous layer 41a, 41b is overgrown by a semiconductor crystal 43. A diode structure 45 is grown on the semiconductor crystal 43.

This diode structure 45 (not shown in further detail), contains for example p-doped and n-doped layers, an active region, reflector layers and other functional layers (none of which are shown). The diode structure 45 can preferably be a light-emitting diode structure, a laser diode structure or an IR diode structure. A bonding layer 46 is disposed above the diode structure 45. Said bonding layer 46 is particularly suitable for bonding the epitaxial substrate to an acceptor substrate as part of the transfer step used in thin-layer technology.

Configuring the porous layer 41a, 41b in two subregions of different pore sizes results in more uniform overgrowth of the porous layer with a semiconductor crystal 43. In particular, lattice defects are reduced or prevented, thereby permitting uniform growth of a light-emitting diode structure or a laser structure, as the case may be.

Possible embodiments are not, however, limited to the growth of light-emitting diode, laser diode or IR diode structures above semiconductor crystal 43. Rather, any desired optoelectronic or electronic structures can be grown above semiconductor crystal 43. Semiconductor crystal 43 particularly preferably has a lattice constant that is identical or similar to that of the base semiconductor wafer 42. Said wafer 42 is particularly preferably a gallium arsenide wafer.

In a further configuration, the entire epitaxial substrate exhibits the same long-range crystallographic order from the grown structures 45 to the wafer 42, said long-range order being mediated via the porous layer 41a, 41b. Further exemplary embodiments of the invention comprise additional layers, such as etch-stop layers, reflector layers or lattice-match layers, within the epitaxial substrate.

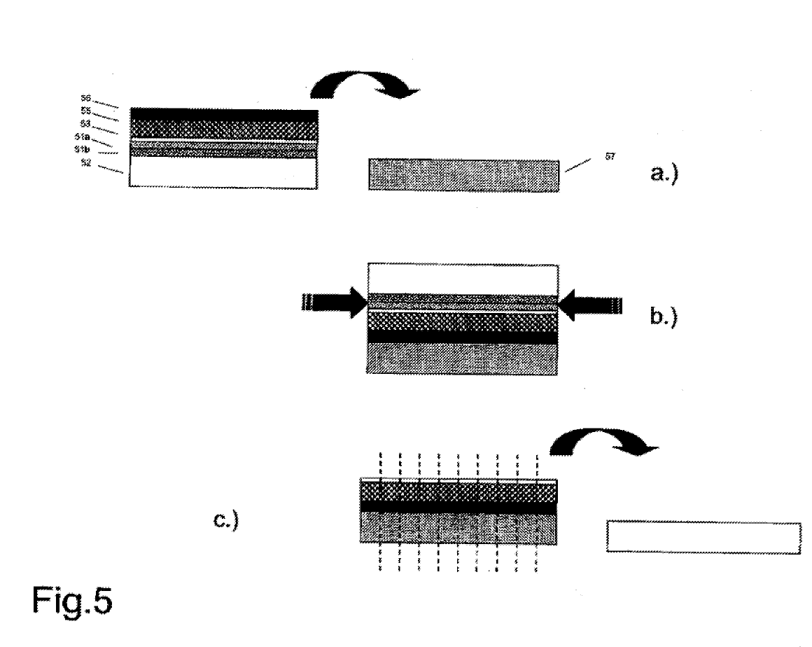

FIG. 5 is a schematic diagram of a method for the simultaneous production of plural thin-layer semiconductor chips. FIG. 5a) illustrates, on the left, an epitaxial substrate according to FIG. 4 with adapted reference numerals and shading. Via bonding layer 56, this epitaxial substrate is brought into contact with an acceptor substrate 57 and bonded thereto using a bonding technique. In Subfigure 5b), two arrows on the left and right sides illustrate schematically how the porous layer is cleaved.

The cleaving of the porous layer can be accomplished by either mechanical or etching processes. The porous layer is cleaved or completely removed as a result. Any remnants of the porous layer can be smoothed out or removed in subsequent method steps by grinding or lapping or in some other fashion. After the cleavage of porous layer 51a, 51b according to Subfigure 5b), the original wafer or the growth substrate 52 is removed, as illustrated schematically in Subfigure 5c). The left-hand portion of FIG. 5c) depicts how the epitaxially grown structures are firmly bonded to the acceptor substrate 57 via a bonding layer.

A remnant of the semiconductor crystal with which the porous layer was overgrown on the epitaxial substrate still persists above the epitaxially grown structures.

This semiconductor crystal is either configured to be very thin, so that it does not interfere with any radiation extraction from the structured layers, or is completely ablated by polishing or selective etching. The structures produced can then for example be singulated into individual chips. The broken lines in FIG. 5c) schematically represent lines along which the heterostructure can be cleaved. If the epitaxially grown structure 55 is an LED structure, then a large number of thin-film LED chips are obtained by singulation similar to that illustrated in FIG. 5c).

Additional embodiments are within the scope of the following claims.

What is claimed is:

1. Method of producing a light-emitting diode chip comprising the steps of:
providing a wafer, wherein the wafer contains a III-V semiconductor material,
producing a porous layer on the wafer, wherein the porous layer contains pores having a pore size, the pore size exhibits a gradient in the porous layer,
epitaxially growing a light-emitting diode structure over the porous layer, the light-emitting diode structure comprises a III-V semiconductor material,
bonding the surface of the light-emitting diode structure which faces away from the porous layer to an acceptor substrate,
detaching the wafer by cleaving or destroying the porous layer, and
separating the light-emitting diode structure into a plurality of light emitting diode chips.

2. The method as in claim 1, wherein the pore size in the porous layer decreases from a center of the porous layer to a surface of the porous layer facing towards the wafer and the pore size in the porous layer decreases from the center of the porous layer to a surface of the porous layer facing away from the wafer.

3. The method as in claim 2, wherein
the porous layer has three or more subregions, each subregion having an average pore size and each subregion being layer-shaped,
each subregion is arranged in parallel to a surface of the wafer facing towards the porous layer and each subregion having the same lateral extension as said surface, and
a middle subregion of said at least three or more subregions has a larger average pore size than the two subregions adjacent to the middle subregion, said middle subregion being arranged in the center of the porous layer.

4. The method as in claim 3 further comprising the following steps:
producing an etch-stop layer directly on the side of the porous layer facing away from the wafer,
producing a semiconductor crystal directly on the side of the etch-stop layer facing away from the porous layer, and
epitaxially growing the light-emitting diode structure directly on the semiconductor crystal,
wherein
the etch-stop layer is configured to protect the semiconductor crystal against an etching solution which is configured to destroy the porous layer.

5. The method as in claim 4, wherein the semiconductor crystal is a mono-crystalline semiconductor crystal.

6. The method as in claim 4, wherein the wafer and semiconductor crystal consist of the same semiconductor material.

7. The method as in claim 4, wherein the wafer and semiconductor crystal have the same crystallographic order.

8. The method as in claim 4, wherein the wafer consists of gallium arsenide.

9. The method as in claim 1, wherein the wafer consists of gallium arsenide.

10. The method as in claim 1 further comprising the following steps:
producing an etch-stop layer directly on the side of the porous layer facing away from the wafer,
producing a semiconductor crystal directly on the side of the etch-stop layer facing away from the porous layer, and
epitaxially growing the light-emitting diode structure directly on the semiconductor crystal,
wherein
the etch-stop layer is configured to protect the semiconductor crystal against an etching solution which is configured to destroy the porous layer.

11. An epitaxial substrate comprising
a wafer, wherein the wafer contains a III-V semiconductor material, and
a porous layer on the wafer, wherein the porous layer contains pores having a pore size, the pore size exhibits a gradient in the porous layer.

12. The epitaxial substrate as in claim 11, wherein the pore size in the porous layer decreases from a center of the porous layer to a surface of the porous layer facing towards the wafer and the pore size in the porous layer decreases from the center of the porous layer to a surface of the porous layer facing away from the wafer.

13. The epitaxial substrate as in claim 12, wherein
the porous layer has three or more subregions, each subregion having an average pore size and each subregion being layer-shaped,
each subregion is arranged in parallel to a surface of the wafer facing towards the porous layer and each subregion having the same lateral extension as said surface, and
a middle subregion of said at least three or more subregions has a larger average pore size than the two subregions adjacent to the middle subregion, said middle subregion being arranged in the center of the porous layer.
